(19) United States
(12) Patent Application Publication
(10) Pub. No.: US 2025/0101302 A1
(43) Pub. Date: Mar. 27, 2025

(54) ß-SIALON FLUORESCENT MATERIAL AND LIGHT EMITTING DEVICE

(71) Applicant: NICHIA CORPORATION, Anan-shi (JP)

(72) Inventors: Yuya TAKAHASHI, Myozai-gun (JP); Takashi KAIDE, Anan-shi (JP); Hiroyuki WATANABE, Itano-gun (JP)

(73) Assignee: NICHIA CORPORATION, Anan-shi (JP)

(21) Appl. No.: 18/894,198

(22) Filed: Sep. 24, 2024

(30) Foreign Application Priority Data
Sep. 25, 2023 (JP) 2023-159394

(51) Int. Cl. C09K 11/77; C09K 11/02; H01L 33/50

(52) U.S. Cl. CPC C09K 11/77348; C09K 11/025; H10H 20/8512

(57) ABSTRACT

A β-SiAlON fluorescent material includes fluorescent material particles having a composition represented by the following formula (I), and a coating layer formed on the surface of the fluorescent material particles and having a refractive index smaller than that of the fluorescent material particles, wherein when the β-SiAlON fluorescent material is measured by inductively coupled plasma-atomic emission spectroscopy, an amount of the coating layer is 0.4% by mass or more relative to a total amount of the fluorescent material particles and the coating layer being 100% by mass:

Si_{6-z}Al_{z}O_{z}N_{8-z}:Eu_{y} (I),

wherein y and z satisfy 0<y≤1.0 and 0<z≤4.2.

### CROSS-REFERENCE TO RELATED APPLICATIONS

The present application claims priority under 35 U.S.C. § 119 to Japanese Patent Application No. 2023-159394, filed on Sep. 25, 2023, the disclosure of which is hereby incorporated by reference in its entirety.

### BACKGROUND

### Technical Field

The present disclosure relates to a β-SiAlON fluorescent material and a light emitting device.

### Description of Related Art

There are known light emitting devices including light emitting diodes (LEDs) and fluorescent materials. The fluorescent materials absorb excitation light emitted from LEDs and emit light having light emission peak wavelengths in a specific wavelength range. Among the fluorescent materials, β-SiAlON fluorescent materials are known, in which the excitation light emitted from LEDs is absorbed to have light emission peak wavelengths in the visible light region.

Japanese Patent Publication No. 2007-326981 discloses a fluorescent material containing a β-SiAlON as a host material and Eu solidly dissolved as a luminescent center and having a 10% diameter of 7 to 20 μm and a 90% diameter of 50 to 90 μm as measured by a laser diffraction particle size distribution measurement method.

Japanese Patent Publication No. 2013-173868 discloses a method for producing a β-SiAlON fluorescent material including at least two calcination steps, wherein in the first calcination step, a fluorescent raw material for the first calcination having a concentration of an activator element lower than that to be obtained is prepared and calcined, and a fluorescent raw material for the second calcination is prepared by further adding an activator element to the resulting first calcined raw material and then calcined.

Fluorescent materials are desired to have a high luminance, and light emitting devices including fluorescent materials are desired to emit light having a high luminous flux.

### SUMMARY

An object of the present disclosure is to provide a β-SiAlON fluorescent material having a high absorption of excitation light and emitting light having a high luminance, and a light emitting device including the β-SiAlON fluorescent material and emitting light having a high luminous flux.

According to a first aspect of the present disclosure, a β-SiAlON fluorescent material including fluorescent material particles having a composition represented by the following formula (I), and a coating layer formed on a surface of the fluorescent material particles and having a refractive index smaller than that of the fluorescent material particles, wherein when the β-SiAlON fluorescent material is measured by inductively coupled plasma-atomic emission spectroscopy, an amount of the coating layer is 0.4% by mass or more relative to a total amount of the fluorescent material particles and the coating layer being 100% by mass:

Si_{6-z}Al_{z}O_{z}N_{8-z}:Eu_{y} (I),

wherein y and z satisfy 0<y≤1.0 and 0<z≤4.2.

According to a second aspect of the present disclosure, a light emitting device including: a wavelength conversion member including the β-SiAlON fluorescent material and a light transmissive material; and a light emitting element having a light emission peak wavelength in a range of 380 nm or more and 500 nm or less.

Certain aspects of the present disclosure allows for providing a β-SiAlON fluorescent material having a high absorption of excitation light and emitting light having a high luminance, and a light emitting device including the β-SiAlON fluorescent material and emitting light having a high luminous flux.

### BRIEF DESCRIPTION OF THE DRAWINGS

A more complete appreciation of embodiments of the disclosure and many of the attendant advantages thereof will be readily obtained by reference to the following detailed description when considered in connection with the accompanying drawings.

FIG. 1 is a schematic cross-sectional view showing an example of a light emitting device according to the present disclosure.

FIG. 2 is a flowchart describing an example of a method for producing a β-SiAlON fluorescent material according to the present disclosure.

FIG. 3 is a flowchart describing an example of a method for producing a β-SiAlON fluorescent material according to the present disclosure.

FIG. 4 is a flowchart describing an example of a method for producing a β-SiAlON fluorescent material according to the present disclosure.

FIG. 5 is an SEM micrograph of a reflected electron image at a magnification of 10,000 times in a cross section of a β-SiAlON fluorescent material according to Example 3.

FIG. 6A is a partially enlarged SEM micrograph of a reflected electron image at a magnification of 30,000 times in a cross section of the β-SiAlON fluorescent material according to Example 3.

FIG. 6B is another partially enlarged SEM micrograph of a reflected electron image at a magnification of 30,000 times in a cross section of the β-SiAlON fluorescent material according to Example 3.

FIG. 7A is an SEM micrograph of a secondary electron image of a β-SiAlON fluorescent material according to Example 1 at a magnification of 5,000 times.

FIG. 7B is an SEM micrograph of a secondary electron image of the β-SiAlON fluorescent material according to Example 1 at a magnification of 100,000 times.

FIG. 8A is an SEM micrograph of a secondary electron image of a β-SiAlON fluorescent material according to Comparative Example 1 at a magnification of 5,000 times.

FIG. 8B is an SEM micrograph of a secondary electron image of the β-SiAlON fluorescent material according to Comparative Example 1 at a magnification of 100,000 times.

FIG. 9A is an SEM micrograph of a secondary electron image of a β-SiAlON fluorescent material according to Comparative Example 2 at a magnification of 5,000 times.

FIG. 9B is an SEM micrograph of a secondary electron image of the β-SiAlON fluorescent material according to Comparative Example 2 at a magnification of 100,000 times.

### DETAILED DESCRIPTION

The following describes a β-SiAlON fluorescent material and a light emitting device according to the present disclosure. Embodiments described below are exemplifications for giving a concrete form to the technical idea of the present disclosure, and the present disclosure is not limited to the following β-SiAlON fluorescent material and light emitting device. The relationships between color names and chromaticity coordinates, and the relationships between wavelength ranges of light and color names of monochromatic lights in the present specification are in accordance with Japanese Industrial Standard (JIS) Z8110. In this specification, the “fluorescent material” is used in the same meaning as a “fluorescent phosphor”.

The β-SiAlON fluorescent material includes fluorescent material particles having a composition represented by the following formula (I), and a coating layer formed on the surface of the fluorescent material particles and having a refractive index smaller than that of the fluorescent material particles, wherein when the β-SiAlON fluorescent material is subjected to measurement by inductively coupled plasma-atomic emission spectroscopy (ICP-AES), an amount of the coating layer is 0.4% by mass or more relative to a total amount of the fluorescent material particles and the coating layer being 100% by mass:

Si_{6-z}Al_{z}O_{z}N_{8-z}:Eu_{y} (I),

wherein y and z satisfy 0<y≤1.0 and 0<z≤4.2.

Since the β-SiAlON fluorescent material includes a coating layer having a refractive index smaller than that of the fluorescent material particles on the surface of the fluorescent material particles having a composition represented by the formula (I), the absorption of light emitted from an excitation light source by the fluorescent material particles is increased, and the light absorbed by the fluorescent material particles can be wavelength-converted to emit light having a high luminance. The refractive index of the fluorescent material particles having a composition represented by the formula (I) approximates the refractive index of silicon nitride Si₃N₄ included in the composition of the β-SiAlON fluorescent material, and the refractive index of light (D line of sodium) having a wavelength of 589.3 nm, which is commonly expressed as the refractive index of optical materials, is approximately 2.06. The refractive index of the coating layer varies depending on raw materials forming the coating layer or elements contained in the raw materials forming the coating layer. The coating layer may be composed of an inorganic substance or an organic substance. When the coating layer is composed of an inorganic substance, the inorganic substance may be a nitride, a halide, or an oxide. The coating layer is preferably an oxide layer composed of an oxide. When the coating layer is composed of an organic substance, examples of the organic substance include those composed of high molecular compounds. When the coating layer is an oxide layer composed of an oxide, the refractive index varies depending on the elements contained in the coating layer. When the coating layer is an oxide layer composed of an oxide containing, for example, silicon, and the oxide contains silicon dioxide, the refractive index of the coating layer upon irradiation with light in the wavelength range of 380 to 780 nm or less is in a range of approximately 1.45 or more and 1.50 or less, which is smaller than that of the fluorescent material particles. When a coating layer having a refractive index smaller than that of the fluorescent material particles is formed on the surface of the fluorescent material particles, the coating layer reduces reflection and scattering of light on the surface of the fluorescent material particles, thereby allowing the light to be transmitted more easily and increasing the light absorptance of the fluorescent material particles. When the light absorptance of the fluorescent material particles is increased, the light absorbed with a high absorptance can be wavelength-converted by the fluorescent material particles to emit light having a high luminance.

When the β-SiAlON fluorescent material is included in a wavelength conversion member of a light emitting device, it is preferred that the wavelength conversion member includes a light transmissive material and the β-SiAlON fluorescent material, and that the difference between the refractive index of the light transmissive material and the refractive index of the coating layer in the β-SiAlON fluorescent material is in a range of 0.01 to 0.80 in terms of absolute value. When the difference between the refractive index of the light transmissive material included in the wavelength conversion member and the refractive index of the coating layer in the β-SiAlON fluorescent material is in the range of 0.01 to 0.80 in terms of absolute value, the difference between the refractive index of the light transmissive material in the wavelength conversion member and the refractive index of the coating layer in the β-SiAlON fluorescent material becomes small, and the light transmissive material and the coating layer reduce reflection and scattering of light, thereby allowing the light to be transmitted more easily and increasing the light absorptance of the fluorescent material particles. In addition, when the difference between the refractive index of the light transmissive material included in the wavelength conversion member and the refractive index of the coating layer in the β-SiAlON fluorescent material is in the range of 0.01 to 0.80 in terms of absolute value, the light absorbed by the fluorescent material particles is wavelength-converted and emitted outside the light emitting device, and even at that time, the wavelength-converted light can be easily transmitted through the coating layer and the light transmissive material to emit light having a high luminous flux from the light emitting device. The difference between the refractive index of the light transmissive material included in the wavelength conversion member and the refractive index of the coating layer in the β-SiAlON fluorescent material may be in a range of 0.01 to 0.70, may be in a range of 0.01 to 0.60, may be in a range of 0.01 to 0.50, may be in a range of 0.02 to 0.30, may be in a range of 0.02 to 0.20, or may be in a range of 0.03 to 0.12, in terms of absolute value. It is more preferred that the refractive index of the light transmissive material in the wavelength conversion member is smaller than that of the coating layer in the β-SiAlON fluorescent material. When the refractive index of the light transmissive material included in the wavelength conversion member is smaller than that of the coating layer in the β-SiAlON fluorescent material, the value of the refractive index becomes progressively smaller in the order of the fluorescent material particles, the coating layer, and the light transmissive material, and the light transmissive material and the coating layer reduce reflection and scattering of light, thereby allowing the light to be transmitted more easily and increasing the light absorptance of the fluorescent material particles. When the value of the refractive index becomes progressively smaller in the order of the fluorescent material particles, the coating layer, and the light transmissive material, the light absorbed by the fluorescent material particles is wavelength-converted and emitted outside the light emitting device, and even at that time, the wavelength-converted light can be easily transmitted through the coating layer and the light transmissive material to emit light having a high luminous flux from the light emitting device. When the light transmissive material included in the wavelength conversion member is a resin and the resin is, for example, a silicone resin, the refractive index of the silicone resin upon irradiation with light having a wavelength of 632.8 nm is approximately 1.40 to 1.55, which is close to the refractive index of the coating layer when the coating layer is an oxide layer composed of an oxide and the oxide layer contains silicon dioxide. When the light transmissive material included in the wavelength conversion member is a resin and the resin is, for example, an epoxy resin, the refractive index of the epoxy resin upon irradiation with light having a wavelength of 589.3 nm is 1.55 to 1.61.

The β-SiAlON fluorescent material preferably has a coating layer formed on the entire surface of the fluorescent material particles having a composition represented by the formula (I). When the coating layer is formed on the entire surface of the fluorescent material particles, light irradiated from an excitation light source is transmitted through the coating layer and is incident on the fluorescent material particles, so that reflection and scattering of light are reduced on the entire surface of the fluorescent material particles to increase the light absorptance, and the light incident with a high absorptance can be wavelength-converted by the fluorescent material particles to emit light having a high luminance.

In the formula (I), the parameter y represents a molar ratio of europium, which is an activating element of the β-SiAlON fluorescent material having a composition represented by the formula (I). The term “molar ratio” refers to a molar amount of each element in one mole of the chemical composition. In the formula (I), the parameter z represents a molar ratio of aluminum or oxygen. In the composition represented by the formula (I), the parameter y represents a molar ratio of Eu as an activating element. The parameter y is more than 0 and 1.0 or less (0<y≤1.0), may be in a range of 0.0001 or more and 0.5 or less (0.0001≤y≤0.5), may be in a range of 0.0005 or more and 0.1 or less (0.0005≤y≤0.1), or may be in a range of 0.001 or more and 0.1 or less (0.001≤y≤0.1). In the formula (I), the parameter z represents a molar ratio of Al or O. In the composition represented by the formula (I), the parameter z is more than 0 and 4.2 or less (0<z≤4.2), may be in a range of 0.0001 or more and 1.0 or less (0.0001≤z≤1.0), may be in a range of 0.0001 or more and 0.8 or less (0.0001≤z≤0.8), may be in a range of 0.0005 or more and 0.5 or less (0.0005≤z≤0.5), or may be in a range of 0.001 or more and 0.25 or less (0.001≤z≤0.25).

The β-SiAlON fluorescent material has a coating layer on the entire surface of the fluorescent material particles when the amount of the coating layer is 0.4% by mass or more relative to the total amount of the fluorescent material particles and the coating layer being 100% by mass, as measured by ICP-AES. In the β-SiAlON fluorescent material, the amount of the coating layer may be 0.5% by mass or more, may be 0.8% by mass or more, or may be 1.0% by mass or more; and may be 5.0% by mass or less, may be 4.0% by mass or less, may be 3.5% by mass or less, or may be 3.0% by mass or less, relative to the total amount of the fluorescent material particles and the coating layer being 100% by mass, as measured by ICP-AES. Considering that the light emitted from the excitation light source is transmitted through the coating layer and reaches the fluorescent material particles to increase the light absorption by the fluorescent material particles, the amount of the oxide layer is preferably 5.0% by mass or less relative to the total amount of the fluorescent material particles and the coating layer being 100% by mass. The amount of the coating layer in the β-SiAlON fluorescent material may be measured by ICP-AES using an inductively coupled plasma-atomic emission spectroscopy (such as Optima 8300, manufactured by PerkinElmer Inc.).

When the coating layer is an oxide layer composed of an oxide, the oxide preferably contains an element being at least one selected from the group consisting of silicon, aluminum, zirconium, and yttrium. With the coating layer composed of an oxide containing an element being at least one selected from the group consisting of silicon, aluminum, zirconium, and yttrium, a coating layer having a refractive index smaller than that of the fluorescent material particles having a composition represented by the formula (I) can be easily formed.

For example, in the case of a coating layer composed of an oxide containing silicon, when the oxide is silicon dioxide, the refractive index of the coating layer is in a range of 1.45 or more and 1.50 or less upon irradiation with light having a wavelength in a range of 380 nm or more and 780 nm or less. For example, in the case of a coating layer composed of an oxide containing aluminum, when the oxide is aluminum oxide, the refractive index of the coating layer is in a range of 1.65 or more and 1.80 or less upon irradiation with light having a wavelength in a range of 380 nm or more and 780 nm or less. For example, in the case of a coating layer composed of an oxide containing zirconium, when the oxide is zirconium oxide, the refractive index of the coating layer is in a range of 1.95 or more and 2.05 or less upon irradiation with light having a wavelength in a range of 380 nm or more and 780 nm or less. For example, in the case of a coating layer composed of an oxide containing yttrium, when the oxide is yttrium oxide, the refractive index of the coating layer is in a range of 1.85 or more and 1.95 or less upon irradiation with light having a wavelength in a range of 380 nm or more and 780 nm or less. When the coating layer is an oxide layer composed of an oxide, the coating layer may contain elements being at least two selected from the group consisting of silicon, aluminum, zirconium, and yttrium; however, it is preferred that the coating layer is composed of an oxide containing one element.

It is preferred that the β-SiAlON fluorescent material has an average particle diameter D, as measured by a Fischer Sub-Sieve Sizer (hereinafter also referred to as “FSSS”) method, in a range of 1 μm or more and 40 μm or less, and a BET specific surface area of 2.5 m²/g or more. When the average particle diameter D measured by the FSSS method is in the range of 1 μm or more and 40 μm or less and the BET specific surface area is 2.5 m²/g or more, the β-SiAlON fluorescent material is considered to have a film-shaped coating layer formed on the entire surface of the fluorescent material particles. The β-SiAlON fluorescent material, which has an average particle diameter D measured by the FSSS method in the range of 1 μm or more and 40 μm or less, preferably has a BET specific surface area of 20 m²/g or less, or may have a BET specific surface area in a range of 2.5 m²/g or more and 20 m²/g or less. The β-SiAlON fluorescent material is presumed to be present in the form of a film in which a dense layer composed of, for example, silicon dioxide is laminated on the surface of the fluorescent material particles having a composition represented by the formula (I) to form an extremely fine unevenness on the surface of the coating layer. The β-SiAlON fluorescent material having a coating layer formed on the surface of the fluorescent material particles has a BET specific surface area of 2.5 m²/g or more, which is higher than that of fluorescent materials having no coating layer formed or having a granular oxide formed on the surface of the fluorescent material particles.

The FSSS method is a type of air permeability method and is a method of measuring a specific surface area by utilizing the flow resistance of air to mainly determine a particle diameter of primary particles. The average particle diameter measured by the FSSS method is a Fisher Sub-Sieve Sizer's number. The average particle diameter D according to the FSSS method can be measured using, for example, a Fisher Sub-Sieve Sizer Model 95 (manufactured by Fisher Scientific Inc.).

The average particle diameter D of the β-SiAlON fluorescent material measured by the FSSS method may be in a range of 2 μm or more and 38 μm or less, may be in a range of 3 μm or more and 35 μm or less, may be in a range of 5 μm or more and 35 μm or less, may be in a range of 5 μm or more and 30 μm or less, may be m or less, may be 20 μm or less, or may be 15 μm or less. The β-SiAlON fluorescent material having a coating layer formed on the surface of the fluorescent material particles has an average particle diameter D measured by the FSSS method in a range of 5 μm or more and 35 μm or less, and may have a BET specific surface area in a range of 2.5 m²/g or more and 20 m²/g or less, or in a range of 3 m²/g or more and 18 m²/g or less, or in a range of 5 m²/g or more and 15 m²/g or less. The β-SiAlON fluorescent material having a coating layer formed on the surface of the fluorescent material particles has an average particle diameter D measured by the FSSS method in a range of 8 μm or more and 20 μm or less, and may have a BET specific surface area in a range of 2.5 m²/g or more and 20 m²/g or less, or in a range of 3 m²/g or more and 18 m²/g or less, or in a range of 5 m²/g or more and 15 m²/g or less. The β-SiAlON fluorescent material has an average particle diameter D measured by the FSSS method in a range of 8 μm or more and 15 μm or less, and may have a BET specific surface area in a range of 2.5 m²/g or more and 20 m²/g or less, or in a range of 3 m²/g or more and 18 m²/g or less, or in a range of 5 m²/g or more and 15 m²/g or less.

The fluorescent material particles having a composition represented by the formula (I) have a β-SiAlON composition, and have better moisture resistance than nitride fluorescent materials having a composition different from that of the β-SiAlON composition. Since the fluorescent material having a β-SiAlON composition represented by the formula (I) has good moisture resistance, the fluorescent material, as in the case of nitride fluorescent materials having a composition different from that of the β-SiAlON composition represented by the formula (I), may have a granular material such as colloidal silica formed on the surface of the fluorescent material particles without coating the entire surface of the fluorescent material with a film-shaped coating to improve the dispersibility of the fluorescent material. In the case where a granular material such as colloidal silica is formed on the surface of the fluorescent material particles, the BET specific surface area does not exceed 2.5 m²/g even when the average particle diameter D measured by the FSSS method is in the range of 1 μm or more and m or less, and the BET specific surface area of the β-SiAlON fluorescent material having an average particle diameter D measured by the FSSS method in the range of 1 m or more and 40 μm or less is 2.5 m²/g or less, may be less than 2.5 m²/g, may be 2.0 m²/g or less, may be 1.5 m²/g or less, or may be 1.0 m²/g or less.

The β-SiAlON fluorescent material preferably may have a particle diameter ratio D/Dm of the average particle diameter D, as measured by the FSSS method, to a volume median diameter Dm, as measured by a laser diffraction particle size distribution measurement method, that is 0.6 or more. The laser diffraction particle size distribution measurement method is a method of measuring a particle size by using scattered light of laser light irradiated on particles without distinguishing between primary and secondary particles. The volume median diameter Dm measured by the laser diffraction particle size distribution measurement method refers to a value where the cumulative volume frequency from the small diameter side reaches 50% in the volume-based particle size distribution measured by the laser diffraction particle size distribution measurement method. The laser diffraction particle size distribution measurement method may be performed using, for example, a laser diffraction particle size distribution measurement apparatus (Mastersizer 3000, manufactured by Malvern Panalytical Ltd.).

For the β-SiAlON fluorescent material, the closer the particle diameter ratio D/Dm of the average particle diameter D, as measured by the FSSS method, to the volume median diameter Dm, as measured by the laser diffraction particle size distribution measurement method, is to 1, the less agglomerated fluorescent material particles are contained and the more primary particles are contained, resulting in good dispersibility. It is desirable for the β-SiAlON fluorescent material to have good dispersibility because, when using the β-SiAlON fluorescent material in a light emitting device, the β-SiAlON fluorescent material is dispersed in a light transmissive material such as a resin and used as a wavelength conversion member. The β-SiAlON fluorescent material having a coating layer on the surface of the fluorescent material particles does not need to have a particle diameter ratio D/Dm as large as 1.0 since the absorption of irradiated light is higher as described above. The particle diameter ratio D/Dm of the β-SiAlON fluorescent material is preferably 0.6 or more, more preferably 0.65 or more, and even more preferably 0.7 or more. A β-SiAlON fluorescent material having no coating layer formed on the surface of the fluorescent material particles, or a β-SiAlON fluorescent material having a granular oxide such as colloidal silica formed on the surface of the fluorescent material particles, has good dispersibility, and may have a particle diameter ratio D/Dm of more than 0.9 and close to 1.0. However, even with good dispersibility, these β-SiAlON fluorescent materials may not emit light with high luminance since the light absorptance is not as high as that of the β-SiAlON fluorescent material having a coating layer formed on the surface of the fluorescent material particles.

In the case where the average particle diameter D measured by the FSSS method is in the range of 1 μm or more and 40 μm or less, when the particle diameter ratio D/Dm is 0.6 or more, the volume median diameter Dm of the β-SiAlON fluorescent material, as measured by the laser diffraction particle size distribution measurement method, may be in a range of 1.66 μm or more and 66 μm or less. When the particle diameter ratio D/Dm is 0.6 or more, the volume median diameter Dm of the β-SiAlON fluorescent material may be in a range of 3 μm or more and 65 μm or less, may be in a range of 5 μm or more and 60 μm or less, may be in a range of 8 μm or more and 55 μm or less, may be 50 μm or less, may be 45 μm or less, or may be 40 μm or less.

The coating layer in the β-SiAlON fluorescent material preferably has a thickness in a range of 50 nm or more and 200 nm or less. The thickness of the coating layer in the β-SiAlON fluorescent material may be in a range of 60 nm or more and 180 nm or less, or may be in a range of 60 nm or more and 150 nm or less. The thickness of the coating layer can be determined by the measurement method described below. When the thickness of the coating layer in the β-SiAlON fluorescent material falls within the range of 50 nm or more and 200 nm or less, the coating layer reduces reflection and scattering of light, which allows the light to be transmitted more easily, increases the light absorptance of the fluorescent material particles, and allows high luminance light to be emitted from the β-SiAlON fluorescent material. In addition, when the thickness of the coating layer in the β-SiAlON fluorescent material falls within the range of 50 nm or more and 200 nm or less, a light emitting device including the β-SiAlON fluorescent material can emit light having a high luminous flux.

The thickness of the coating layer in the β-SiAlON fluorescent material can be measured as follows.

In an image of one of two or more compartments of a cross section of one β-SiAlON fluorescent material obtained by dividing an image of the cross section of the one β-SiAlON fluorescent material into two or more compartments, a line indicating the inside of the coating layer is defined as an inner line, a line indicating the outside of the coating layer is defined as an outer line, a line connecting one end of the inner line and one end of the outer line is defined as a first end line, and a line connecting the other end of the inner line and the other end of the outer line is defined as a second end line; a thickness of the coating layer in each compartment is calculated from an area of the coating layer surrounded by the inner line, the outer line, the first end line, and the second end line relative to an average value of a sum of the length of the inner line and the length of the outer line, by the following formula (1); and the sum of the thicknesses of the coating layer calculated for each compartment of the cross section is divided by the number of compartments in the cross section of the one β-SiAlON fluorescent material to determine an average thickness of the coating layer, which can be designated as the thickness of the coating layer in the β-SiAlON fluorescent material.

Coating layer thickness=[area of coating layer in cross section/(length of outer line of coating layer+length of inner line of coating layer)/2] (1)

As for the cross-sectional image of the β-SiAlON fluorescent material, the β-SiAlON fluorescent material is embedded in a resin, the resin is cured and then cut to expose the cross section of the β-SiAlON fluorescent material, the surface is polished using sandpaper and then finished using a cross section polisher (CP), and the surface can be observed using a field emission scanning electron microscope (FE-SEM) to obtain an SEM micrograph. The resin used to embed the β-SiAlON fluorescent material is preferably an epoxy resin to easily distinguish the cross section of the β-SiAlON fluorescent material. The cross-sectional image of one β-SiAlON fluorescent material may be taken at any magnification that allows the inner and outer lines of the coating layer to be measured, and is preferably taken at a magnification of, for example, 5,000 to 50,000 times, so that the thickness of the coating layer can be measured as described above. The cross-sectional image of one β-SiAlON fluorescent material is divided into two or more compartments; and depending on the size of the one β-SiAlON fluorescent material, the cross-sectional image of the one β-SiAlON fluorescent material is preferably divided into two or more and 10 or less compartments, may be divided into 3 or more and 8 or less compartments, or may be divided into 3 or more and 7 or less compartments. The one β-SiAlON fluorescent material is typically selected from β-SiAlON fluorescent materials in which a cross section of the center or near the center of the fluorescent material core can be observed at a magnification of 5,000 to 50,000 times using a field emission scanning electron microscope (FE-SEM). The one compartment is selected from compartments in which the inner and outer lines of the coating layer can be observed within the above magnification range.

The β-SiAlON fluorescent material emits light having a light emission peak wavelength in a range of 520 nm or more and 560 nm or less upon irradiation with light having a light emission peak wavelength in a range of 380 nm or more and 500 nm or less.

The β-SiAlON fluorescent material can be used in a light emitting device. The light emitting device includes a wavelength conversion member including the above-mentioned β-SiAlON fluorescent material and a light transmissive material, and a light emitting element having a light emission peak wavelength in a range of 380 nm or more and 500 nm or less. The difference between the refractive index of the light transmissive material and the refractive index of the coating layer in the β-SiAlON fluorescent material is preferably in a range of 0.01 to 0.80 in terms of absolute value. The light transmissive material in the wavelength conversion member preferably has a refractive index smaller than that of the coating layer in the β-SiAlON fluorescent material. When the difference between the refractive index of the light transmissive material in the wavelength conversion member and the refractive index of the coating layer in the β-SiAlON fluorescent material is small, the reflection and scattering of light are reduced, thereby allowing the light to be transmitted more easily, increasing the light absorptance of the fluorescent material particles, and allowing high luminance light to be emitted from the light emitting device. When the refractive index of the light transmissive material in the wavelength conversion member is smaller than that of the coating layer in the β-SiAlON fluorescent material, the reflection and scattering of light emitted from an excitation light source are further reduced, thereby allowing the light to be transmitted more easily, further increasing the light absorptance of the fluorescent material particles, and allowing higher luminance light to be emitted from the light emitting device.

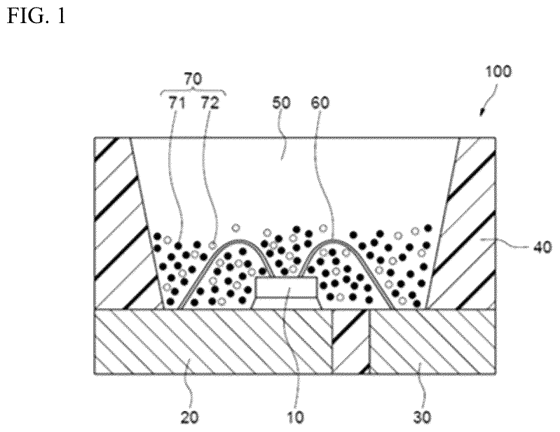

FIG. 1 is a schematic cross-sectional view showing an example of the light emitting device.

Alight emitting device 100 includes a package having a recessed portion formed by lead electrodes 20 and 30 and a molded body 40, a light emitting element 10, and a wavelength conversion member 50 that covers the light emitting element 10. The light emitting element 10 is disposed in the recessed portion of the package, and is electrically connected to a pair of positive and negative lead electrodes 20 and 30 provided on the molded body 40 via a conductive wire 60. The wavelength conversion member 50 is filled in the recessed portion of the package to cover the light emitting element 10, and seals the recessed portion of the package. The wavelength conversion member 50 contains, for example, a fluorescent material 70 that converts the wavelength of light emitted from the light emitting element 10 and a resin, and is formed to cover the light emitting element 10 disposed in the recessed portion of the light emitting device 100. The fluorescent material 70 contains a first fluorescent material 71 as the β-SiAlON fluorescent material, and may contain a second fluorescent material 72 having a composition different from that of the β-SiAlON fluorescent material. The pair of positive and negative lead electrodes 20 and 30 are partially exposed on the outer surface of the package. The light emitting device 100 emits light upon receiving electric power supplied from the outside through these lead electrodes 20 and 30.

A light emitting element can be used as an excitation light source for the light emitting device. The light emitting element has a light emission peak wavelength in a range of 380 nm or more and 500 nm or less, preferably in a range of 400 nm or more and 480 nm or less, more preferably in a range of 420 nm or more and 470 nm or less, and may also be in a range of 420 nm or more and 460 nm or less. The use of a light emitting element having a light emission peak wavelength in the range of 380 nm or more and 500 nm or less as the excitation light source enables the light emitting device to emit mixed-color light of light emitted from the light emitting element and fluorescence emitted from the fluorescent material.

For the light emitting element, a semiconductor light emitting element using a nitride semiconductor (In_{X}Al_{Y}Ga_{1-X-Y}N, 0≤X, 0≤Y, and X+Y≤1) is preferably used. The use of a semiconductor light emitting element as the excitation light source for the light emitting device enables obtaining a stable light emitting device having high efficiency, high output linearity with respect to input, and high resistance to mechanical shock. The light emitting element preferably has a light emission spectrum with a full width at half maximum of, for example, 30 nm or less.

The light emitting device includes the above-mentioned β-SiAlON fluorescent material. The β-SiAlON fluorescent material, which includes fluorescent material particles having a composition represented by the formula (I), is preferably excited by light in a wavelength range of 380 nm or more and 500 nm or less to emit fluorescence having a light emission peak wavelength in a range of 520 nm or more and 560 nm or less. The light emitting device may include a first fluorescent material containing the β-SiAlON fluorescent material, and a second fluorescent material having a composition different from that of the β-SiAlON fluorescent material, and emitting fluorescence having a light emission peak wavelength different from that of the first fluorescent material.

The first fluorescent material can be contained in a wavelength conversion member that covers, for example, an excitation light source to form a light emitting device. In the light emitting device including the excitation light source covered with the wavelength conversion member containing the first fluorescent material, the first fluorescent material absorbs a part of the light emitted from the excitation light source to emit fluorescence having a light emission peak wavelength different from that of the light emitted from the excitation light source.

The content of the first fluorescent material contained in the light emitting device is not particularly limited. For example, the content of the first fluorescent material may be 1 part by mass or more and 200 parts by mass or less, preferably 2 parts by mass or more and 180 parts by mass or less, relative to 100 parts by mass of a resin constituting the wavelength conversion member.

The first fluorescent material and/or the second fluorescent material (hereinafter simply referred to as “fluorescent material”), together with a light transmissive material, constitute a wavelength conversion member that covers the light emitting element. A resin can be used as the light transmissive material constituting the wavelength conversion member, and examples of the resin include a silicone resin and an epoxy resin.

In addition to the light transmissive material and the fluorescent material, the wavelength conversion member may further contain materials such as a filler and a light diffusing material. For example, when a light diffusing material is contained, the directionality of the light emitting element can be relaxed to increase a viewing angle. Examples of the filler include silica, titanium oxide, zinc oxide, zirconium oxide, and alumina. When the wavelength conversion member contains a filler, the content thereof can be selected appropriately depending on the purpose and other factors. For example, the content of the filler may be 1% by mass or more and 20% by mass or less relative to the resin.

The following describes a method for producing a β-SiAlON fluorescent material.

The method for producing a β-SiAlON fluorescent material preferably includes providing fluorescent material particles having a composition represented by the formula (I), and forming a coating layer on the surface of the fluorescent material particles. The method for producing a β-SiAlON fluorescent material may include dispersing fluorescent material particles after providing the fluorescent material particles and before forming a coating layer. The method for producing a β-SiAlON fluorescent material may include washing the resulting fluorescent material particles after providing the fluorescent material particles and before forming a coating layer. When the method for producing a β-SiAlON fluorescent material includes dispersing fluorescent material particles, it is preferred that the method includes washing fluorescent material particles before dispersing the fluorescent material particles in a liquid, and it is more preferred that the method includes washing and dispersing fluorescent material particles. The method for producing a β-SiAlON fluorescent material may include drying the resulting β-SiAlON fluorescent material after forming a coating layer on the surface of the fluorescent material particles. The method may include performing heat treatment after forming a coating layer on the surface of the fluorescent material particles. The method for producing a β-SiAlON fluorescent material may include redispersing the resulting β-SiAlON fluorescent material after forming a coating layer on the surface of the fluorescent material particles.

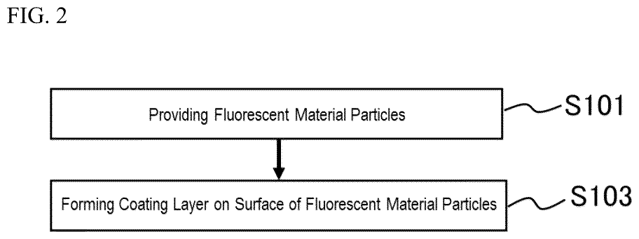

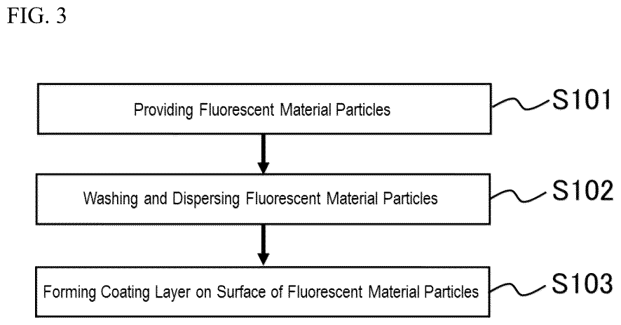

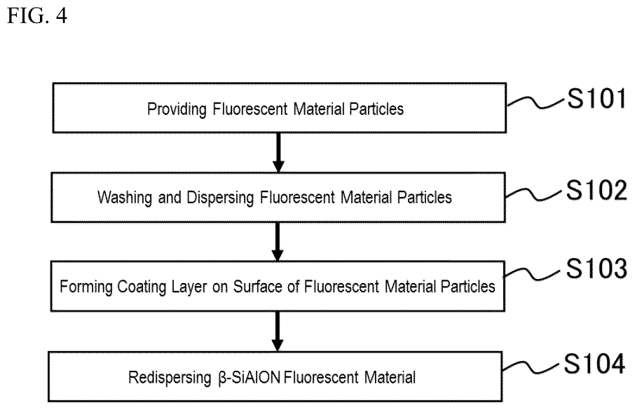

FIGS. 2 to 4 are flowcharts each showing an example of the method for producing a β-SiAlON fluorescent material. As shown in FIG. 2, the method for producing a β-SiAlON fluorescent material preferably includes providing fluorescent material particles S101, and forming a coating layer on the surface of the fluorescent material particles S103. As shown in FIG. 3, the method for producing a β-SiAlON fluorescent material may include washing and dispersing fluorescent material particles S102 after providing the fluorescent material particles S101 and before forming a coating layer on the surface of the fluorescent material particles S103. As shown in FIG. 4, the method for producing a β-SiAlON fluorescent material may include redispersing the resulting β-SiAlON fluorescent material S104 after forming a coating layer on the surface of the fluorescent material particles S103.

Providing fluorescent material particles includes preparing a calcined product having a composition represented by the formula (I) by calcining a raw material mixture, obtaining a pulverized product by pulverizing the calcined product, and obtaining a heat-treated product by heat-treating the pulverized product, wherein obtaining a pulverized product and obtaining a heat-treated product may be repeated two or more times in this order. For providing fluorescent material particles, the method described in Japanese Unexamined Patent Publication No. 2019-135312 may be referred to. For the fluorescent material particles, the commercially available ones may be used.

The raw material mixture is obtained by mixing an aluminum-containing compound, metallic europium or a europium-containing compound, and silicon nitride such that each element contained in the compound or metallic europium satisfies the composition represented by the formula (I). Examples of the aluminum-containing compound include AlN, Al₂O₃, and Al(OH)₂.

Examples of the europium-containing compound include Eu₂O₃, EuN, and EuF₃. The average particle diameter of the metal or compound used as a raw material may usually be large enough to exist as a powder, and is, for example, 0.01 μm or more and 20 μm or less. The raw material mixture may contain a flux such as a halide, as necessary. When the raw material mixture contains a flux, the reaction between the raw materials is further accelerated, and the solid phase reaction proceeds uniformly. Examples of the halide include chlorides or fluorides of rare earth metals, alkaline earth metals, and alkali metals. The raw material mixture preferably contains compounds such that the elements in the compounds contained in the raw material mixture satisfy the molar ratios of the elements in the composition represented by the formula (I).

For preparing a calcined product by calcining the raw material mixture in providing fluorescent material particles, the raw material mixture is preferably calcined at a temperature of 1,850° C. or higher and 2,100° C. or lower in an atmosphere containing nitrogen gas and at a pressure of atmospheric pressure (approximately 0.1 MPa) or more and 200 MPa or less to obtain a calcined product. In the atmosphere containing nitrogen gas, the content of nitrogen gas in the atmosphere is preferably 90% by volume or more, more preferably 95% by volume or more.

In providing fluorescent material particles, obtaining a pulverized product by pulverizing the resulting calcined product may include not only coarsely pulverizing or crushing powder agglomerated bodies in which the powder of the calcined product is agglomerated, but also finely pulverizing the calcined product to be a pulverized product having a predetermined size. The calcined product may be pulverized using a dry pulverizer such as a ball mill, vibration mill, hammer mill, roll mill, or jet mill. In obtaining a pulverized product, the calcined product may be pulverized together with a compound containing an activating element to be the activating element of the fluorescent material particles. When the pulverization and heat treatment are performed two or more times in this order, the calcined product may be pulverized together with a compound containing an activating element to be the activating element of the fluorescent material particles in the second pulverization.

In providing fluorescent material particles, obtaining a heat-treated product by heat-treating the resulting pulverized product preferably includes obtaining a heat-treated product by heat-treating the pulverized product at a temperature of 1,850° C. or higher and 2,100° C. or lower in an inert gas atmosphere and at a pressure of atmospheric pressure (approximately 0.1 MPa) or more and 200 MPa or less. The inert gas atmosphere means an atmosphere containing a gas such as argon, helium, or nitrogen as a main component. The inert gas atmosphere may contain oxygen as an inevitable impurity. In the present specification, an atmosphere having an oxygen concentration of 15% by volume or less is defined as the inert gas atmosphere. In heat-treating a pulverized product, the pulverized product may be heat-treated together with a compound containing an activating element to be the activating element of the fluorescent material particles. In the present specification, in providing fluorescent material particles, the heat treatment of the pulverized product may be referred to as the first heat treatment. In providing fluorescent material particles, even when the pulverization of the calcined product and the heat treatment of the pulverized product are performed two or more times in this order, the heat treatment performed to provide the fluorescent material particles is referred to as the first heat treatment.

Providing fluorescent material particles may include obtaining an annealed product by subjecting the heat-treated product to an annealing treatment at a temperature lower than the heat treatment temperature used in obtaining the heat-treated product in a rare gas atmosphere. The rare gas atmosphere may contain at least one rare gas such as helium, neon, or argon, and preferably contains at least argon in the atmosphere. The rare gas atmosphere may contain oxygen, hydrogen, nitrogen, and others in addition to the rare gas. The content of the rare gas in the rare gas atmosphere is preferably 95% by volume or more, more preferably 99% by volume or more.

In washing fluorescent material particles, the resulting fluorescent material particles are brought into contact with an acidic solution or a basic solution and washed. The fluorescent material particles may be brought into contact with an acidic solution or a basic solution, and then washed with a liquid such as ion-exchanged water. By bringing the fluorescent material particles into contact with an acidic solution or a basic solution, decomposition products decomposed during the second heat treatment, which are contained in the fluorescent material particles, can be eliminated. In washing fluorescent material particles, the acidic solution used can be an acidic solution containing an inorganic acid such as hydrofluoric acid or nitric acid, or an acidic substance such as hydrogen peroxide. In washing fluorescent material particles, the basic solution used can be a basic solution containing a hydroxide containing alkali metals or a basic substance such as ammonia. Specific examples of the basic substance include at least one selected from the group consisting of LiGH, NaOH, KOH, RbOH, CsOH, and NH₃. The fluorescent material particles may be brought into contact with an acidic solution or a basic solution for a period of 10 minutes or more and 30 hours or less, or for a period of 1 hour or more and 25 hours or less. The temperature at which the fluorescent material particles are brought into contact with an acidic solution or a basic solution may be in a range of room temperature (approximately 20° C.) or higher and 300° C. or lower, may be in a range of 30° C. or higher and 200° C. or lower, or may be in a range of 40° C. or higher and 150° C. or lower, to obtain fluorescent material particles in which decomposition products contained in the heat-treated product are efficiently eliminated. The fluorescent material particles may be brought into contact with an acidic solution or a basic solution, and then washed with a liquid medium. Examples of the liquid medium include deionized water. The duration of washing with the liquid medium is, for example, 10 minutes or more and 30 hours or less, or may be 30 minutes or more and 25 hours or less.

In the method for producing a β-SiAlON fluorescent material, washing fluorescent material particles may include, after the washing process, performing a crushing treatment, a pulverization treatment, or a classification treatment, and drying. As the classification treatment, for example, at least one of wet dispersion, wet sieving, dewatering, drying, and dry sieving is preferably performed. The drying temperature is preferably 60° C. or higher and 120° C. or lower.

In the method for producing a β-SiAlON fluorescent material, dispersing fluorescent material particles refers to dispersing the resulting fluorescent material particles in a liquid. The liquid in which the fluorescent material particles are dispersed may be deionized water or a liquid containing at least one selected from the group consisting of ethanol, 1-propanol, and 2-propanol. The liquid may contain a catalyst such as ammonia.

In forming a coating layer on the surface of the fluorescent material particles, it is preferred that the fluorescent material particles are brought into contact with a solution containing a metal alkoxide to form a coating layer on the surface of the fluorescent material particles. Alternatively, a solution containing a metal alkoxide may be added dropwise to a reaction solution, which is a liquid in which the fluorescent material particles are dispersed, to cause a hydrolysis reaction between the fluorescent material particles and the metal alkoxide and to form a coating layer on the surface of the fluorescent material particles. When a solution containing a metal alkoxide is added dropwise to fluorescent material particles dispersed in a liquid to cause a hydrolysis reaction, a coating layer can be formed on the entire surface of the fluorescent material particles.

In forming a coating layer on the surface of the fluorescent material particles, it is preferred that the temperature at which the fluorescent material particles are brought into contact with the solution containing a metal alkoxide is around room temperature and a temperature higher than the freezing point temperature of the solvent contained in the solution containing a metal alkoxide and/or the solvent contained in the reaction solution containing the fluorescent material particles, to prevent solidification of the solution containing a metal alkoxide. The temperature around room temperature at which the fluorescent material particles are brought into contact with the solution containing a metal alkoxide is approximately 25° C., ranging from 15° C. to 35° C. The temperature at which the fluorescent material particles are brought into contact with the solution containing a metal alkoxide may be higher than 0° C. and 70° C. or lower, or may be higher than 0° C. and 50° C. or lower.

In forming a coating layer on the surface of the fluorescent material particles, the time during which the fluorescent material particles are brought into contact with the solution containing a metal alkoxide is preferably 1 hour or more, may be 1.5 hours or more, may be 2 hours or more, and preferably 5 hours or more, to increase the coating ratio of the coating layer on the surface of the fluorescent material particles; and may be more than 24 hours or less to improve productivity.

The metal alkoxide is a metal alkoxide containing an element being at least one selected from the group consisting of silicon, aluminum, zirconium, and yttrium. The metal alkoxide is preferably a silane compound having two or more alkoxyl groups. Specific examples of the metal alkoxide include methyltrimethoxysilane, methyltriethoxysilane, ethyltrimethoxysilane, ethyltriethoxysilane, propyltrimethoxysilane, propyltriethoxysilane, tetramethoxysilane, tetraethoxysilane, tetrapropoxysilane, aluminum triethoxide, aluminum tripropoxide, aluminum tribudoxide, aluminum triisopropoxide, zirconium tetrapropoxide, zirconium tetrabutoxide, yttrium(III) isopropoxide, and yttrium(III) budoxide. The metal alkoxide is preferably tetraethoxysilane in consideration of workability and easy availability.

The fluorescent material particles are brought into contact with a solution containing a metal alkoxide to hydrolyze and condensation-polymerize the metal alkoxide, so that a coating layer is formed on the surface of the fluorescent material particles. For example, when the metal alkoxide is tetraethoxysilane (Si(OC₂H₅)₄), the fluorescent material particles are brought into contact with a solution containing tetraethoxysilane (Si(OC₂H₅)₄) and the tetraethoxysilane is hydrolyzed to form orthosilicic acid (Si(OH)₄), and then a dehydration reaction proceeds by condensation polymerization of orthosilicic acid (Si(OH)₄), so that a coating layer containing silicon dioxide (SiO₂) is formed on the surface of the fluorescent material particles. The coating layer contains silicon dioxide (SiO₂) formed by hydrolysis and condensation polymerization of tetraethoxysilane. The coating layer may also partially contain a silicon compound in which hydroxyl groups (OH) remain.

The solution containing a metal alkoxide preferably contains a metal alkoxide in such an amount that the amount of the coating layer obtained by hydrolysis and condensation polymerization of the metal alkoxide is 0.4% by mass or more relative to the total amount of the fluorescent material particles and the coating layer being 100% by mass. The solution containing a metal alkoxide may contain a metal alkoxide in such an amount that the amount of the coating layer obtained by hydrolysis and condensation polymerization of the metal alkoxide is 5.0% by mass or less relative to the total amount of the fluorescent material particles and the coating layer being 100% by mass. In the solution containing a metal alkoxide, the amount of the coating layer obtained by hydrolysis and condensation polymerization of the metal alkoxide may be 0.5% by mass or more, may be 0.8% by mass or more, or may be 1.0% by mass or more; and may be 4.0% by mass or less, may be 3.5% by mass or less, or may be 3.0% by mass or less, relative to the total amount of the fluorescent material particles and the coating layer being 100% by mass.

In forming a coating layer on the surface of the fluorescent material particles, the coating layer may be formed, for example, by a sol-gel method, by a chemical vapor deposition (CVD) method using a solution containing a metal alkoxide, or by an atomic layer deposition (ALD) method using a solution containing a metal alkoxide.

In forming a coating layer on the surface of the fluorescent material particles, it is preferred that a basic catalyst be present when the fluorescent material particles are brought into contact with the solution containing a metal alkoxide. The presence of a basic catalyst when the fluorescent material particles are brought into contact with the solution containing a metal alkoxide promotes the reactions of hydrolysis and condensation polymerization of the metal alkoxide even at temperatures lower than the ambient temperature, so that a coating layer with a high coating ratio can be formed on the surface of the fluorescent material particles. The basic catalyst used may be, but is not particularly limited to, at least one selected from the group consisting of ammonium, ammonium carbonate, ammonium hydrogen carbonate, ammonium formate, ammonium acetate, sodium carbonate, and sodium hydrogen carbonate. The basic catalyst may be present by being added to the reaction solution in which the fluorescent material particles are dispersed when the fluorescent material particles are brought into contact with the solution containing a metal alkoxide. The basic catalyst may be present by being added to the solution containing a metal alkoxide when the fluorescent material particles are brought into contact with the solution containing a metal alkoxide. When a basic catalyst is added to the reaction solution or to the solution containing a metal alkoxide, a compound serving as a basic catalyst may be added to each solution in a range of 0.001 mol/L or more and 1.0 mol/L or less.

The solution containing a metal alkoxide preferably contains water and/or alcohol. The solution containing a metal alkoxide preferably contains water and/or alcohol as a solvent. For water, deionized water can be used. For alcohol, at least one selected from the group consisting of methanol, ethanol, 1-propanol, and 2-propanol can be used.

The method for producing a β-SiAlON fluorescent material may include two or more times of forming a coating layer on the surface of the fluorescent material particles. In other words, the method may include two or more times of bringing the fluorescent material particles into contact with the solution containing a metal alkoxide. When the method includes two or more times of bringing the fluorescent material particles into contact with the solution containing a metal alkoxide, in order to ensure that the amount of the coating layer is in the range of 0.4% by mass or more and 5.0% by mass or less relative to the total amount of the fluorescent material particles and the coating layer being 100% by mass, the number of times of bringing the fluorescent material particles into contact with the solution containing a metal alkoxide may be two or more times, or may be three or more times, and may be five times or less. When bringing the fluorescent material particles into contact with the solution containing a metal alkoxide two or more times, the temperature at which the particles are contacted is below the ambient temperature in each process.

In the method for producing a β-SiAlON fluorescent material, forming a coating layer on the surface of the fluorescent material particles may include forming a coating layer on the surface of the fluorescent material particles and then heat-treating the fluorescent material particles and the coating layer formed on the surface of the fluorescent material particles. In the present specification, the heat treatment of the fluorescent material particles and the coating layer formed on the surface of the fluorescent material particles may be referred to as the second heat treatment. The temperature of the second heat treatment is preferably higher than 250° C. and 500° C. or lower. By forming a coating layer on the surface of the fluorescent material particles and heat-treating (second heat treatment) the coating layer, a dehydration reaction proceeds in the coating layer containing hydroxyl groups (OH), thereby obtaining a β-SiAlON fluorescent material having the coating layer firmly adhered to the surface of the fluorescent material particles. The oxygen in the coating layer also acts on the fluorescent material particles and bonds with the element (Si or Al) derived from the fluorescent material particles, thereby forming a coating layer that is more firmly bonded to the fluorescent material particles. The temperature of the heat treatment (second heat treatment) at which the coating layer is formed on the surface of the fluorescent material particles may be higher than 250° C. and 500° C. or lower, may be higher than 250° C. and 450° C. or lower, or may be 300° C. or higher and 400° C. or lower. The second heat treatment is preferably performed in air or in an inert gas atmosphere. When the β-SiAlON fluorescent material having the coating layer formed on the surface of the fluorescent material particles is subjected to the second heat treatment in air or in an inert gas atmosphere, a dehydration reaction proceeds in the coating layer containing hydroxyl groups (OH), and a part of the element (such as Si) contained in the coating layer is more firmly bonded to the element (such as Si or Al) derived from the fluorescent material particles via oxygen. The duration of the second heat treatment may be, but is not particularly limited to, 1 hour or more and 20 hours or less, may be 2 hours or more and 15 hours or less, or may be 3 hours or more and 10 hours or less. When the duration of the second heat treatment is 1 hour or more and 20 hours or less, the second heat treatment may not affect the fluorescent material particles, the amount of the contained hydroxyl groups (OH) is reduced, and the coating layer can be formed in close contact with the surface of the fluorescent material particles. The method for producing a β-SiAlON fluorescent material may include post-treatments such as crushing, pulverizing, and classifying the resulting heat-treated, the fluorescent material particles, or the β-SiAlON fluorescent material after each heat treatment of the first or second heat treatment.

The method for producing a β-SiAlON fluorescent material may include redispersing the resulting β-SiAlON fluorescent material after forming the coating layer on the surface of the fluorescent material particles. By redispersing the β-SiAlON fluorescent material having the coating layer formed on the surface of the fluorescent material particles, agglomeration of the β-SiAlON fluorescent material having the coating layer formed on the surface of the fluorescent material particles can be reduced, thereby obtaining a β-SiAlON fluorescent material having good dispersibility to light transmissive materials in the production of a light emitting device. In the method for producing a β-SiAlON fluorescent material, redispersing the β-SiAlON fluorescent material specifically refers to dispersing the β-SiAlON fluorescent material in a liquid. The liquid in which the β-SiAlON fluorescent material is dispersed may be the same liquid in which the fluorescent material particles are dispersed. Redispersing the β-SiAlON fluorescent material may include at least one of the following treatments: wet dispersion, wet sieving, dewatering, drying, and dry sieving. The time during which the β-SiAlON fluorescent material is redispersed is preferably 1 hour or more and 10 hours or less, may be 2 hours or more and 8 hours or less, or may be 3 hours or more and 6 hours or less.

The method for producing a β-SiAlON fluorescent material may include redispersing the β-SiAlON fluorescent material and then taking the β-SiAlON fluorescent material out of the liquid, followed by drying. When the β-SiAlON fluorescent material is redispersed and then dried, at least one element selected from the group consisting of silicon, aluminum, zirconium, and yttrium is bonded to the surface of the fluorescent material particles in a state containing hydroxyl groups (OH), and then drying can remove hydrogen from the hydroxyl groups (OH), thereby forming a coating layer in close contact with the surface of the fluorescent material particles. Drying can be performed using any of the equipment commonly used in the industry, such as a hot air dryer, a vacuum dryer, a conical dryer, a rotary evaporator, or a spray dryer. The drying temperature is preferably in a range of 60° C. or higher and 120° C. or lower. The drying time is, but is not particularly limited to, preferably 1 hour or more and 30 hours or less, more preferably 2 hours or more and 25 hours or less, and even more preferably 3 hours or more and 24 hours or less.

### EXAMPLES

The present disclosure is hereunder specifically described with reference to the following Examples. The present disclosure is not limited to the following Examples.

### Example 1

### Providing Fluorescent Material Particles

Silicon nitride (Si₃N₄), aluminum nitride (AlN), aluminum oxide (Al₂O₃), and europium oxide (Eu₂O₃) were weighed in a molar ratio of Si:Al:Eu of 5.79:0.21:0.011, and mixed to obtain a raw material mixture. In the process, aluminum nitride and aluminum oxide were weighed and mixed in a molar ratio of AlN:Al₂O₃ of 75:25. The raw material mixture was filled into a crucible made of boron nitride, and calcined at 2,030° C. for 10 hours in a nitrogen atmosphere (nitrogen: 99% by volume or more) at 0.92 MPa (gauge pressure) to obtain a calcined product.

The resulting calcined product was coarsely pulverized using a mortar and pestle, and then finely pulverized for 20 hours using a ball mill with two types of silicon nitride balls having diameters (Φ) of 20 mm and 25 mm and a porcelain pot for a first pulverization treatment to obtain a pulverized product. In the first pulverization process, the pulverization treatment was performed by adding 0.003 mol of europium oxide (Eu₂O₃) to 1 mol of the calcined product.

The resulting pulverized product was then filled into a crucible made of boron nitride, and subjected to a second heat treatment (second first heat treatment) at 2,000° C. for 10 hours in a nitrogen atmosphere (nitrogen: 99% by volume or more) at 0.92 MPa (gauge pressure) to obtain a heat-treated product.

The resulting heat-treated product was then subjected to a second pulverization treatment under the same conditions as the first pulverization process to obtain a pulverized product. In the second pulverization process, the pulverization treatment was performed by adding 0.002 mol of europium oxide (Eu₂O₃) to 1 mol of the heat-treated product.

The resulting pulverized product was then filled into a crucible made of boron nitride, and subjected to a third heat treatment at 1,980° C. for 10 hours in a nitrogen atmosphere (nitrogen: 99% by volume or more) at 0.92 MPa (gauge pressure) to obtain a heat-treated product, which was then used as fluorescent material particles having a composition represented by the formula (I).

### Washing and Dispersing Fluorescent Material Particles

The resulting fluorescent material particles were brought into contact with a sodium hydroxide aqueous solution containing 33% by mass of NaOH at 130° C. for 20 hours, and then washed with deionized water and dried. Thereafter, the fluorescent material particles were subjected to a classification treatment in which the particles were crushed by wet dispersion, passed through a sieve, and stirred in deionized water to settle the fluorescent material for a certain period of time, and the supernatant was discarded, and then dried at a temperature of 90° C. or higher and 105° C. or lower. The drying temperature may be in a range of 60° C. or higher and 120° C. or lower.

The dried fluorescent material particles were mixed with 180 mL of an alcohol preparation (Solmix AP-7) containing ethanol, 1-propanol, and 2-propanol, and 63 mL of ammonia water containing 11.0% by mass of ammonia as a basic catalyst to prepare a reaction solution. In the process, 100 g of the resulting fluorescent material particles were added to the reaction solution and stirred at room temperature to disperse the fluorescent material particles.

### Forming Coating Layer on Surface of Fluorescent Material Particles

An ethanol solution of tetraethoxysilane (Si(OC₂H₅)₄) (tetraethoxysilane concentration of 28% by mass) in an amount of 10.4 g was used as a solution containing a metal alkoxide. In the solution containing a metal alkoxide, the element contained in the coating layer is Si, and the solution containing a metal alkoxide contains tetraethoxysilane, which is 3.0% by mass of SiO₂ relative to 100% by mass of the fluorescent material particles. While stirring the reaction solution, the solution containing a metal alkoxide was added dropwise to the reaction solution over 150 minutes. After the dropwise addition of the solution containing a metal alkoxide was completed, the reaction solution was stirred for 60 minutes to bring the fluorescent material particles into contact with the solution containing a metal alkoxide in the presence of ammonia as a basic catalyst. The stirring was then stopped, and the fluorescent material particles having a Si-containing coating layer formed on the surface were taken out of the reaction solution and dried in a dryer at a temperature of 60° C. or higher and lower than 120° C. for 15 hours or more to form a coating layer on the surface of the fluorescent material particles, thereby obtaining a β-SiAlON fluorescent material according to Example 1. The β-SiAlON fluorescent material according to Example 1 has fluorescent material particles and a coating layer that is an oxide layer composed of a Si-containing oxide (SiO₂) on the surface of the fluorescent material particles. The coating layer has a refractive index in a range of approximately 1.45 or more and 1.50 or less upon irradiation with light having a wavelength in a range of 380 nm to 780 nm.

### Example 2

### Redispersing β-SiAlON Fluorescent Material

The β-SiAlON fluorescent material in an amount of 200 g, obtained in the same or similar manner as in Example 1, was crushed by wet dispersion. Specifically, the β-SiAlON fluorescent material was redispersed by wet dispersion in which the β-SiAlON fluorescent material was placed in a polyethylene bottle containing 200 g of deionized water and 250 g of polyethylene beads and the bottle was rotated. After being redispersed for 3 hours, the β-SiAlON fluorescent material was taken out and dried in a dryer at a temperature of 60° C. or higher and lower than 120° C. for 15 hours or more to obtain a β-SiAlON fluorescent material according to Example 2.

### Example 3

A β-SiAlON fluorescent material according to Example 3 was obtained in the same or similar manner as in Example 2, except that in redispersing the β-SiAlON fluorescent material in the liquid, the wet dispersion time was changed to 5 hours.

### Comparative Example 1

Fluorescent material particles obtained in the same or similar manner as in Example 1, except that no coating layer was formed on the surface of the fluorescent material particles, were used as a β-SiAlON fluorescent material according to Comparative Example 1.

### Comparative Example 2

Fluorescent material particles in an amount of 100 g were placed in 400 g of deionized water; 0.15 mL of a colloidal silica solution (silicon dioxide concentration of 20% by mass) was added dropwise using a dropper while stirring the fluorescent material particles to obtain a slurry; hydrochloric acid was then added to the slurry until the pH reached 2; and the slurry was further stirred for 5 minutes. After being stirred for 5 minutes, an ammonia aqueous solution was added to the slurry until the pH reached approximately 7 for neutralization, the stirring was stopped to allow the fluorescent material particles to settle, and the supernatant was discarded.

After one more process of washing the fluorescent material particles with deionized water, settling the fluorescent material particles, and discarding the supernatant, the fluorescent material particles having granular colloidal silica formed on the surface were taken out and dried in a dryer at a temperature of 60° C. or higher and lower than 120° C. for 15 hours or more to obtain a β-SiAlON fluorescent material according to Comparative Example 2 having granular colloidal silica on the surface of the fluorescent material particles.

The β-SiAlON fluorescent materials according to Examples and Comparative Examples were subjected to the following evaluations. The results are shown in Table 1. In Table 1, the symbol “-” indicates that there is no corresponding item or numerical value.

### Average Particle Diameter D

For the β-SiAlON fluorescent materials according to Examples and Comparative Examples, the average particle diameter D was measured by the FSSS method using a Fisher Sub-Sieve Sizer Model 95 (manufactured by Fisher Scientific Inc.).

### Volume Median Diameter Dm

For the β-SiAlON fluorescent materials according to Examples and Comparative Examples, the volume median diameter Dm, where the cumulative volume frequency from the small diameter side reaches 50%, was measured using a laser diffraction particle size distribution measurement apparatus (Mastersizer 3000, manufactured by Malvern Panalytical Ltd.).

### Particle Diameter Ratio D/Dm

The particle diameter ratio D/Dm of the average particle diameter D to the volume median diameter Dm was calculated.

### Relative Luminance (%)

For the β-SiAlON fluorescent materials according to Examples and Comparative Examples, the light emission spectrum was measured using a quantum efficiency measurement system (QE-2000, manufactured by Otsuka Electronics Co., Ltd.). The light emission peak wavelength of the excitation light used in the quantum efficiency measurement system was 450 nm. The luminance was measured from the light emission spectrum. The luminance of each β-SiAlON fluorescent material was measured as a relative value to the luminance of the β-SiAlON fluorescent material according to Comparative Example 1 being 100%.

### Absorptance at 450 nm (%)

For the β-SiAlON fluorescent materials according to Examples and Comparative Examples, using a quantum efficiency measurement system (QE-2000, manufactured by Otsuka Electronics Co., Ltd.), the ratio of the absorbed light quantum number at 450 nm of each β-SiAlON fluorescent material to the excitation light quantum number at 450 nm of the excitation light having a light emission peak wavelength of 450 nm was calculated as the absorptance at 450 nm.

### Luminous Flux (%) of Light Emitting Device

The β-SiAlON fluorescent material according to each of Examples and Comparative Examples was used as a first fluorescent material 71. A potassium silicofluoride fluorescent material was used as a second fluorescent material 72. The first fluorescent material 71 and the second fluorescent material 72 were blended such that the target chromaticity coordinates in the chromaticity diagram of the CIE1931 color system were (x=0.262, y=0.223) to obtain a fluorescent material 70, and the fluorescent material 70 was mixed with a silicone resin to obtain a resin composition. The content of the fluorescent material 70 in the resin composition is in the range of 20 parts by mass or more and 40 parts by mass or less relative to 100 parts by mass of the silicone resin. In addition, for example, the content of the β-SiAlON fluorescent material contained as the first fluorescent material is in the range of 20 parts by mass or more and 40 parts by mass or less, and the content of the second fluorescent material is in the range of 60 parts by mass or more and 80 parts by mass or less, relative to 100 parts by mass of the fluorescent material 70. The content of the β-SiAlON fluorescent material contained in the resin composition may vary depending on the target color and the size of the light emitting device to be obtained. Next, a molded body 40 having a recessed portion was prepared, a light emitting device 10 made of a gallium nitride compound semiconductor having a light emission peak wavelength of 451 nm was disposed on a first lead 20 located on the bottom surface of the recessed portion, and the electrodes of the light emitting device 10 were then connected to the first lead 20 and a second lead 30 with a wire 60, respectively. The resin composition was injected into the recessed portion of the molded body 40 using a syringe to cover the light emitting element 10, and the resin composition was cured to form a wavelength conversion member, thereby producing a light emitting device 100 shown in FIG. 1. The luminous flux of the light emitting device 100 including the β-SiAlON fluorescent material according to each of Examples and Comparative Examples was measured using an integral total luminous flux measurement apparatus. The luminous flux of the light emitting device using the β-SiAlON fluorescent material according to each of Examples is expressed as a relative value (%) to the luminous flux of the light emitting device using the β-SiAlON fluorescent material according to Comparative Example 2 being 100%.

### Amount of Coating Layer

The Si contained in the entire β-SiAlON fluorescent material according to each of Examples and Comparative Examples and the Si in the coating layer were measured by the inductively coupled plasma-atomic emission spectrometry method using an inductively coupled plasma-atomic emission spectroscopy (ICP-AES) (Optima 8300, manufactured by PerkinElmer Inc.), and the amount of the coating layer to the entire amount of the β-SiAlON fluorescent material was calculated from the amount of Si in the coating layer to the entire amount of Si in the β-SiAlON fluorescent material. Even if the element contained in the coating layer is not silicon, the element contained in the coating layer and the element contained in the entire β-SiAlON fluorescent material can be measured using ICP-AES to calculate the amount of the coating layer to the entire amount of the β-SiAlON fluorescent material.

### BET Specific Surface Area

For the β-SiAlON fluorescent materials according to Examples and Comparative Examples, the BET specific surface area was measured by a single-point BET method using nitrogen gas as the adsorption gas.

### Coating Layer Thickness

Each β-SiAlON fluorescent material was embedded in a resin, the resin was cured and then cut to expose the cross section of the β-SiAlON fluorescent material, the surface was polished using sandpaper and then finished using a cross section polisher (CP), and the surface was observed using a field emission scanning electron microscope (FE-SEM) to obtain an SEM micrograph. The resin used to embed the β-SiAlON fluorescent material was an epoxy resin since the cross section of the β-SiAlON fluorescent material was easily distinguishable.

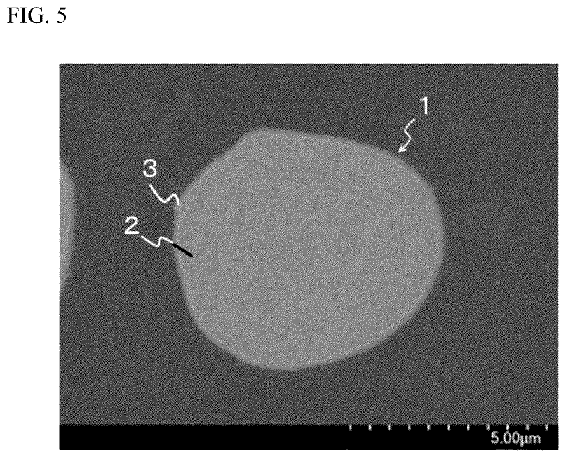

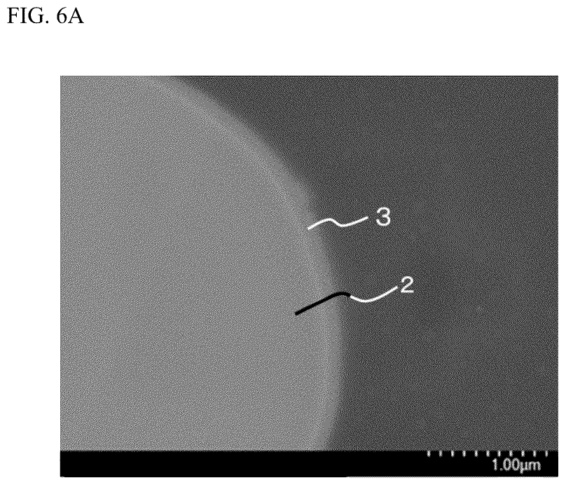

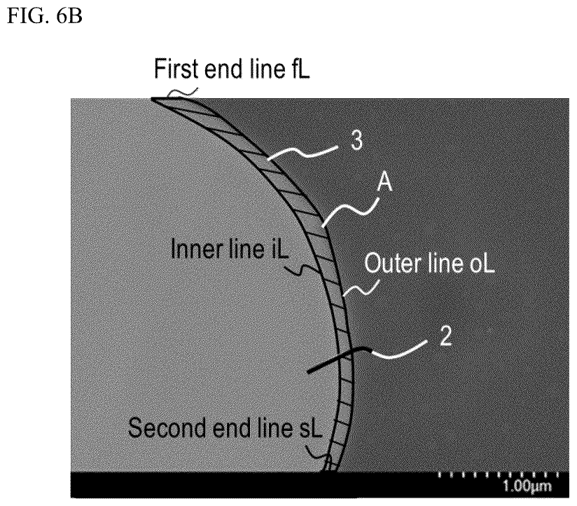

FIG. 5 is an SEM micrograph showing a cross section of the β-SiAlON fluorescent material according to Example 3. In order to easily observe the coating layer, the magnification of 10,000 times was further increased, and the cross section of the β-SiAlON fluorescent material shown in FIG. 5 was divided into three compartments. FIG. 6A is an enlarged SEM micrograph at a magnification of 30,000 times showing one of the three compartments in the cross section of the β-SiAlON fluorescent material shown in FIG. 5. FIG. 6B, as in FIG. 6A, is an enlarged SEM micrograph at a magnification of 30,000 times showing one of the three compartments in the cross section of the β-SiAlON fluorescent material shown in FIG. 5, and to explain the measurement of the thickness of the coating layer, an inner line iL, an outer line oL, a first end line fL, a second end line sL, and an area A of the coating layer are filled out on the drawing. As shown in FIG. 6B, in the image of one of three compartments of the cross section of one β-SiAlON fluorescent material obtained by dividing the image of the cross section of the one β-SiAlON fluorescent material into three compartments, a line indicating the inside of the coating layer 3 is defined as the inner line iL, a line indicating the outside of the coating layer 3 is defined as the outer line oL, a line connecting one end of the inner line iL and one end of the outer line oL is defined as the first end line fL, and a line connecting the other end of the inner line iL and the other end of the outer line oL is defined as the second end line sL; and a thickness of the coating layer in one compartment is calculated from the area A of the coating layer 3 surrounded by the inner line iL, the outer line oL, the first end line fL, and the second end line sL relative to an average value of a sum of the length of the inner line iL and the length of the outer line oL, by the following formula (1). The sum of the thicknesses of the coating layer calculated for each compartment of the cross section is divided by the number of compartments in the cross section of the one β-SiAlON fluorescent material to determine an average thickness of the coating layer, which can be designated as a thickness of the coating layer of the one β-SiAlON fluorescent material.

$$Coating layer thickness = [ area of coating layer in cross section / ( length of outer line of coating layer + length of inner line of coating layer ) / 2 ] \qquad ( 1 )$$

### SEM Micrograph

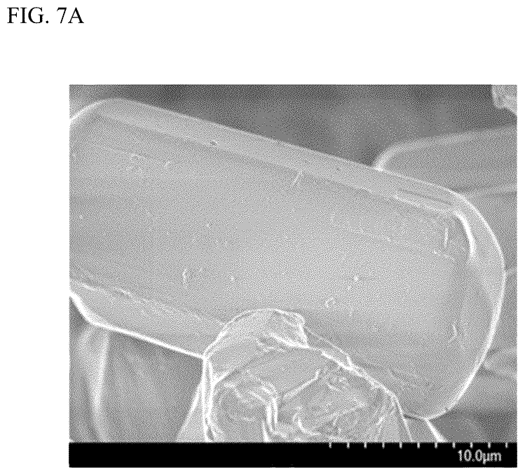

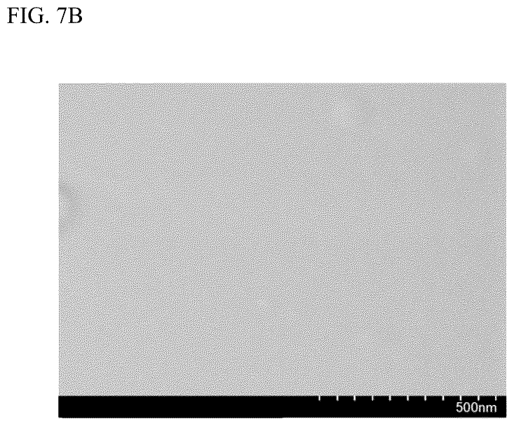

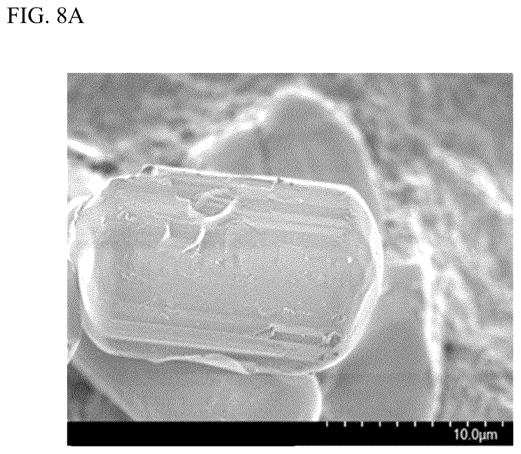

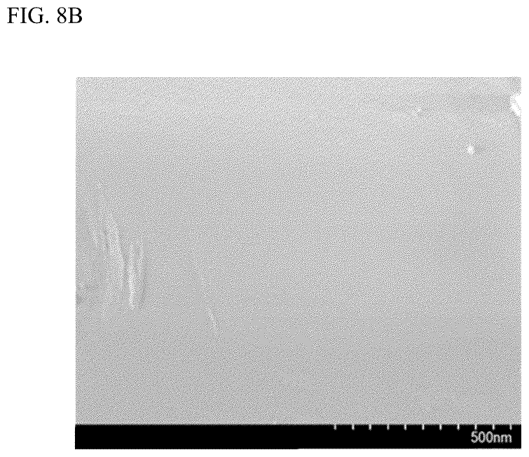

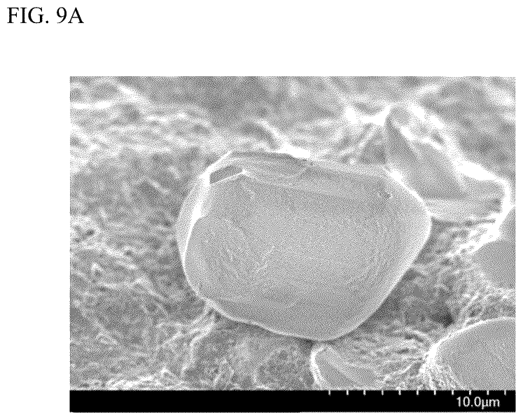

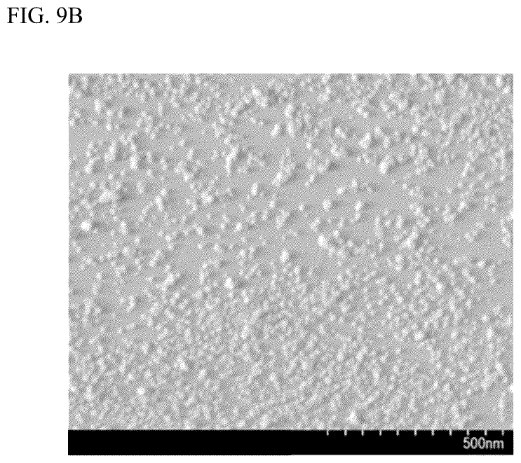

A scanning electron microscope (SEM) was used to obtain an SEM micrograph of a secondary electron image of each β-SiAlON fluorescent material. FIG. 7A is an SEM micrograph of a secondary electron image of the β-SiAlON fluorescent material according to Example 1 at a magnification of 5,000 times, and FIG. 7B is an SEM micrograph of a secondary electron image of the β-SiAlON fluorescent material according to Example 1 at a magnification of 100,000 times. FIG. 8A is an SEM micrograph of a secondary electron image of the β-SiAlON fluorescent material according to Comparative Example 1 at a magnification of 5,000 times, and FIG. 8B is an SEM micrograph of a secondary electron image of the β-SiAlON fluorescent material according to Comparative Example 1 at a magnification of 100,000 times. FIG. 9A is an SEM micrograph of a secondary electron image of the β-SiAlON fluorescent material according to Comparative Example 2 at a magnification of 5,000 times, and FIG. 9B is an SEM micrograph of a secondary electron image of the β-SiAlON fluorescent material according to Comparative Example 2 at a magnification of 100,000 times.

TABLE 1

| | | | | | | | | | | | Relative |
|---|---|---|---|---|---|---|---|---|---|---|---|
| | | | Average | Volume | | | BET | | | | luminous |
| | | | particle | median | Particle | Coating | specific | Thickness | | | flux of light |
| | | | diameter | diameter | diameter | layer | surface | of coating | Relative | Absorptance | emitting |
| | Coating | Redispersion | D | Dm | ratio | (% by | area | layer | luminance | at 450 nm | device |
| | layer | (hours) | (μm) | (μm) | D/Dm | mass) | (m²/g) | (nm) | (%) | (%) | (%) |
| Example 1 | film- | — | 10.0 | 15.1 | 0.66 | 2.8 | 8.45 | — | 106.4 | 74.4 | 101.1 |
| | shaped | | | | | | | | | | |
| Example 2 | film- | 3 | 9.8 | 13.7 | 0.72 | 2.8 | 9.43 | — | 105.4 | 73.5 | 100.6 |
| | shaped | | | | | | | | | | |
| Example 3 | film- | 5 | 9.7 | 12.7 | 0.76 | 2.8 | 9.44 | 96.6 | 107.0 | 73.5 | 100.4 |
| | shaped | | | | | | | | | | |
| Comparative | non | — | 9.8 | 11.3 | 0.87 | less than | 0.24 | — | 100.0 | 69.0 | — |
| Example 1 | | | | | | 0.01 | | | | | |
| Comparative | granular | — | 9.8 | 11.5 | 0.85 | 0.19 | 0.61 | — | 96.3 | 67.8 | 100.0 |
| Example 2 | | | | | | | | | | | |

In the β-SiAlON fluorescent materials according to Examples 1 to 3, the amount of the coating layer containing Si, as measured by ICP-AES, was in the range of 0.4% by mass or more and 5.0% by mass or less relative to the total amount of the fluorescent material particles and the coating layer being 100% by mass, and the film-shaped coating layer was formed on the entire surface of the fluorescent material particles having the composition represented by the formula (I). In the β-SiAlON fluorescent materials according to Examples 1 to 3, the average particle diameter D measured by the FSSS method was in the range of 9.0 μm or more and 10.0 μm or less, the BET specific surface area was in the range of 2.5 m²/g or more and 20 m²/g or less, which was large relative to the average particle diameter, and the film-shaped coating layer was formed on the entire surface of the fluorescent material particles. The β-SiAlON fluorescent materials according to Examples 1 to 3, since the film-shaped coating layer having a refractive index smaller than that of the fluorescent material particles was formed on the entire surface of the fluorescent material particles having the composition represented by the formula (I), had a light absorptance at 450 nm, i.e., at the light emission peak wavelength of the excitation light, smaller than that of the β-SiAlON fluorescent material according to Comparative Example 1 or 2, and emitted light having a relative luminance higher than that of the β-SiAlON fluorescent material according to Comparative Example 1.

The β-SiAlON fluorescent materials according to Examples 1 to 3 each had a particle diameter ratio D/Dm of 0.6 or more and had good dispersibility. The β-SiAlON fluorescent materials according to Examples 2 and 3 each were redispersed in a liquid after the coating layer was formed on the surface of the fluorescent material particles, thereby reducing the agglomeration of the β-SiAlON fluorescent material particles. Therefore, the β-SiAlON fluorescent materials according to Examples 2 and 3 each had a particle diameter ratio D/Dm larger than that of the β-SiAlON fluorescent material according to Example 1, resulting in better dispersibility to the light transmissive material. The light emitting device including the β-SiAlON fluorescent material according to each of Examples 1 to 3 had good dispersibility of the β-SiAlON fluorescent material to the light transmissive material and high absorptance of the excitation light in the β-SiAlON fluorescent material, resulting in efficient wavelength conversion and high luminous flux of light emitted from the light emitting device.

In the β-SiAlON fluorescent material according to Example 3, as shown in FIGS. 5, 6A, and 6B, the film-shaped coating layer 3 was formed on the entire surface of the fluorescent material particles 2. As shown in FIGS. 6A and 6B, in the SEM micrograph showing one of the three compartments in the cross section of the β-SiAlON fluorescent material, the inner line iL of the coating layer 3, the outer line oL of the coating layer 3, the first end line fL connecting one end of the inner line iL and one end of the outer line oL, and the second end line sL connecting the other end of the inner line iL and the other end of the outer line oL can be drawn; and the thickness of the coating layer in one compartment can be calculated by the formula (1). The thickness of the coating layer can be determined by dividing the cross section of one β-SiAlON fluorescent material into a plurality of compartments, calculating the thickness of the coating layer for each compartment, and dividing the sum of the thicknesses of the coating layer in each compartment by the number of compartments in the cross section of the one β-SiAlON fluorescent material. The thickness of the coating layer in the β-SiAlON fluorescent material according to Example 3 was in the range of 50 nm or more and 200 nm or less, more specifically, in the range of 50 nm or more and 100 nm or less, so that the coating layer reduced reflection and scattering of light, allowing the light to be transmitted more easily, and increased the light absorptance of the fluorescent material particles, resulting in high luminance light emitted from the β-SiAlON fluorescent material. Since the amount (% by mass) of the coating layer was the same for the β-SiAlON fluorescent materials according to Examples 1 to 3, the β-SiAlON fluorescent material according to Example 3 was subjected to the measurement of the coating layer thickness as a representative. Since the amount (% by mass) of the coating layer in the β-SiAlON fluorescent materials according to Examples 1 and 2 is the same as that of the β-SiAlON fluorescent material according to Example 3, it can be presumed that the thickness of the coating layer for the β-SiAlON fluorescent materials according to Examples 1 and 2 is similar to that of the β-SiAlON fluorescent material according to Example 3.

In the β-SiAlON fluorescent material according to Example 1, as shown in FIGS. 7A and 7B, the surface of the β-SiAlON fluorescent material was smooth, and the entire surface of the fluorescent material particles was coated with a coating layer. Since the β-SiAlON fluorescent material according to Example 1 has a BET specific surface area larger than that of the β-SiAlON fluorescent materials according to Comparative Examples 1 and 2, it is presumed that a dense unevenness is present on the surface of the coating layer, which is a dense film-shaped layer composed of silicon dioxide.

The β-SiAlON fluorescent materials according to Comparative Examples 1 and 2 had an average particle diameter D measured by the FSSS method in the range of 9.0 m or more and 10.0 μm or less, which was similar in size to the β-SiAlON fluorescent materials according to Examples 1 to 3, but had a smaller BET specific surface area of less than 2.5 m²/g. Since the β-SiAlON fluorescent material according to Comparative Example 1 had no coating layer in place, almost no silicon was observed by ICP-AES other than that contained in the fluorescent material particles. The β-SiAlON fluorescent material according to Comparative Example 2 had granular colloidal silica formed on the surface of the fluorescent material particles, the amount of the colloidal silica was as small as 0.19% by mass relative to the total amount of the fluorescent material particles and the granular colloidal silica, and the BET specific surface area was also as small as less than 2.5 m²/g. Since the β-SiAlON fluorescent materials according to Comparative Examples 1 and 2 had no coating layer present on the surface of the fluorescent material particles or had the granular oxide present on the surface of the fluorescent material particles, the scattering and reflection of the excitation light incident on each β-SiAlON fluorescent material were not reduced, and the light absorption at a wavelength of 450 nm was lower than that of the β-SiAlON fluorescent materials according to Examples 1 to 3, resulting in not high luminance. The β-SiAlON fluorescent materials according to Comparative Examples 1 and 2 had a particle diameter ratio D/Dm of 0.6 or more, specifically 0.8 or more, and had high dispersibility to the light transmissive material. However, the relative luminous flux of the light emitting device using the β-SiAlON fluorescent material according to Comparative Example 2 was not higher than that of the light emitting device using the β-SiAlON fluorescent material according to each of Examples 1 to 3.

As shown in FIGS. 8A and 8B, the β-SiAlON fluorescent material according to Comparative Example 1 has no coating layer in place, and no noticeable unevenness cannot be observed on the surface of the fluorescent material particles being the β-SiAlON fluorescent material.

It is difficult to observe in FIG. 9A, but as shown in FIG. 9B, the β-SiAlON fluorescent material according to Comparative Example 2 has granular oxides composed of colloidal silica formed on the surface of the fluorescent material particles.

The embodiments according to the present disclosure include the following β-SiAlON fluorescent material and light emitting device.

The β-SiAlON fluorescent material according to the present disclosure can be used as a fluorescent material included in a wavelength conversion member of a light emitting device; and the light emitting device including the β-SiAlON fluorescent material can be suitably used for applications such as illumination light sources, LED displays, backlight sources for liquid crystal displays, traffic lights, illuminated switches, various sensors, and various indicators.

1. A β-SiAlON fluorescent material comprising:
fluorescent material particles having a composition represented by the following formula (I), and
a coating layer disposed on a surface of the fluorescent material particles and having a refractive index smaller than that of the fluorescent material particles,
wherein when the β-SiAlON fluorescent material is measured by inductively coupled plasma-atomic emission spectroscopy, an amount of the coating layer is 0.4% by mass or more relative to a total amount of the fluorescent material particles and the coating layer being 100% by mass:
Si_{6-z}Al_{z}O_{z}N_{8-z}:Eu_{y} (I),
wherein y and z satisfy 0<y≤1.0 and 0<z≤4.2.

2. The β-SiAlON fluorescent material according to claim 1, wherein the coating layer comprises an oxide, and the oxide contains at least one element selected from the group consisting of silicon, aluminum, zirconium, and yttrium.

3. The β-SiAlON fluorescent material according to claim 1, wherein the β-SiAlON fluorescent material has an average particle diameter D, as measured by a Fischer Sub-Sieve Sizer method, in a range of 1 μm or more and 40 μm or less, and a BET specific surface area that is 2.5 m²/g or more.

4. The β-SiAlON fluorescent material according to claim 1, wherein the β-SiAlON fluorescent material has a particle diameter ratio D/Dm of an average particle diameter D, as measured by a Fisher Sub-Sieve Sizer method, to a volume median diameter Dm, as measured by a laser diffraction particle size distribution measurement method, that is 0.6 or more.

5. The β-SiAlON fluorescent material according to claim 1, wherein the coating layer has an average thickness, as determined by the following method, in a range of 50 nm or more and 200 nm or less,
wherein in an image of one of two or more compartments of a cross section of one β-SiAlON fluorescent material obtained by dividing an image of the cross section of the one β-SiAlON fluorescent material into two or more compartments, when a line indicating the inside of the coating layer is defined as an inner line, a line indicating the outside of the coating layer is defined as an outer line, a line connecting one end of the inner line and one end of the outer line is defined as a first end line, and a line connecting the other end of the inner line and the other end of the outer line is defined as a second end line; a thickness of the coating layer in each compartment is calculated from an area of the coating layer surrounded by the inner line, the outer line, the first end line, and the second end line relative to an average value of a sum of the length of the inner line of the coating layer and the length of the outer line of the coating layer, by the following formula (1); and
the sum of the thicknesses of the coating layer calculated for each compartment of the cross section is divided by the number of compartments in the cross section of the one β-SiAlON fluorescent material to determine the average thickness of the coating layer:
coating layer thickness=[area of coating layer in cross section/(length of outer line of coating layer+length of inner line of coating layer)/2] (1).

6. The β-SiAlON fluorescent material according to claim 1, wherein the coating layer is disposed on the entire surface of the fluorescent material particles.

7. A light emitting device comprising: a wavelength conversion member including the β-SiAlON fluorescent material according to claim 1 and a light transmissive material; and a light emitting element having a light emission peak wavelength in a range of 380 nm or more and 500 nm or less.

8. The light emitting device according to claim 7, wherein a refractive index of the light transmissive material is smaller than a refractive index of the coating layer in the β-SiAlON fluorescent material.
